(19) United States
(12) Patent Application Publication
(10) Pub. No.: US 2012/0224329 A1
(43) Pub. Date: Sep. 6, 2012

(54) PORTABLE ELECTRONIC DEVICE WITH ENHANCED HEAT DISSIPATION

(75) Inventors: HONG LI, Shenzhen City (CN); XUE-DONG TANG, Shenzhen City (CN); KE-HUI PENG, Shenzhen City (CN); PING LI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/196,012

(22) Filed: Aug. 2, 2011

(30) Foreign Application Priority Data
Mar. 2, 2011 (CN) 201110049895.4

(51) Int. Cl. H05K 7/20

(52) U.S. Cl. 361/720; 361/704

(57) ABSTRACT

A portable electronic device includes a circuit board, a heat sink a hinge and a heat dissipating plate. The circuit board is equipped with a heat generating component. The heat sink is for dissipating heat generated by the heat generating component. The heat dissipating plate is pivotably connected to the heat sink by the hinge for helping with the heat dissipation of the heat sink.

### BACKGROUND

1. Technical Field

The present disclosure generally relates to portable electronic devices, and particularly to portable electronic devices with enhanced heat dissipation.

2. Description of Related Art

With the development of electronic/information devices, portable electronic devices are becoming more popular. The heat dissipation performance of a portable electronic device is now of vital importance, due to the elevated user requirements of faster operation speed, and smaller more compact portable electronic devices.

Therefore, it is necessary to provide a portable electronic device with enhanced heat dissipation.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure.

FIG. 1 is a schematic view of a portable electronic device in accordance with an exemplary embodiment of the present disclosure.

FIG. 2 is an exploded view of the portable electronic device of FIG. 1.

FIG. 3 is an exploded view of a heat sink, a hinge and a heat dissipating plate of the portable electronic device in FIG. 1.

FIG. 4 is an assembled, schematic view of the heat sink, the hinge and the heat dissipating plate in FIG. 3.

### DETAILED DESCRIPTION

Reference will now be made to the drawings to describe the present portable electronic device.

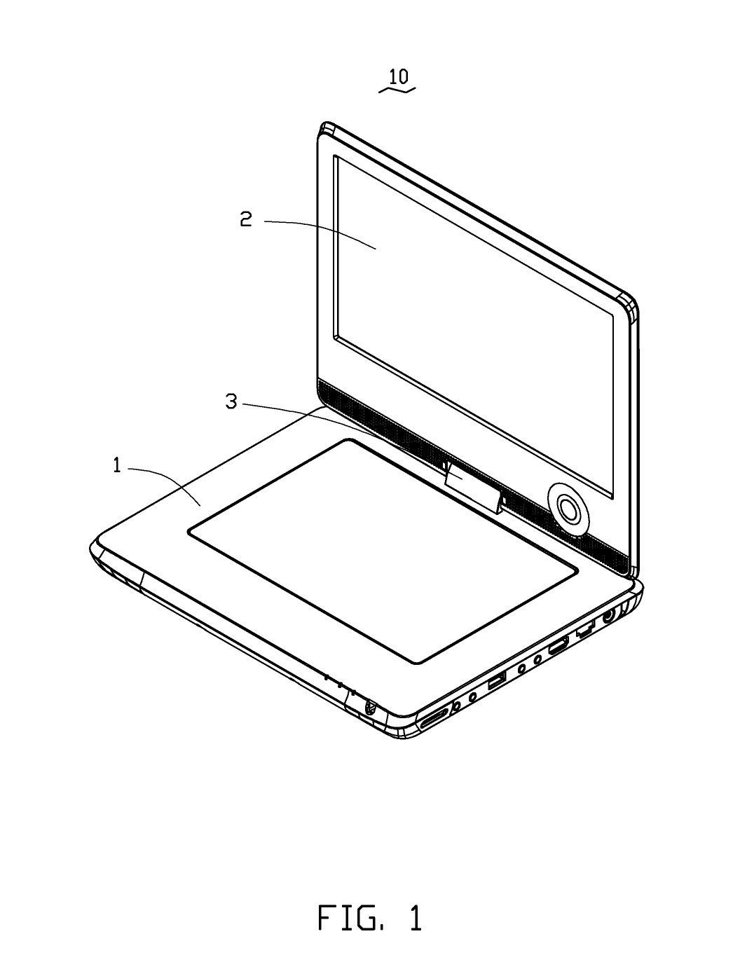

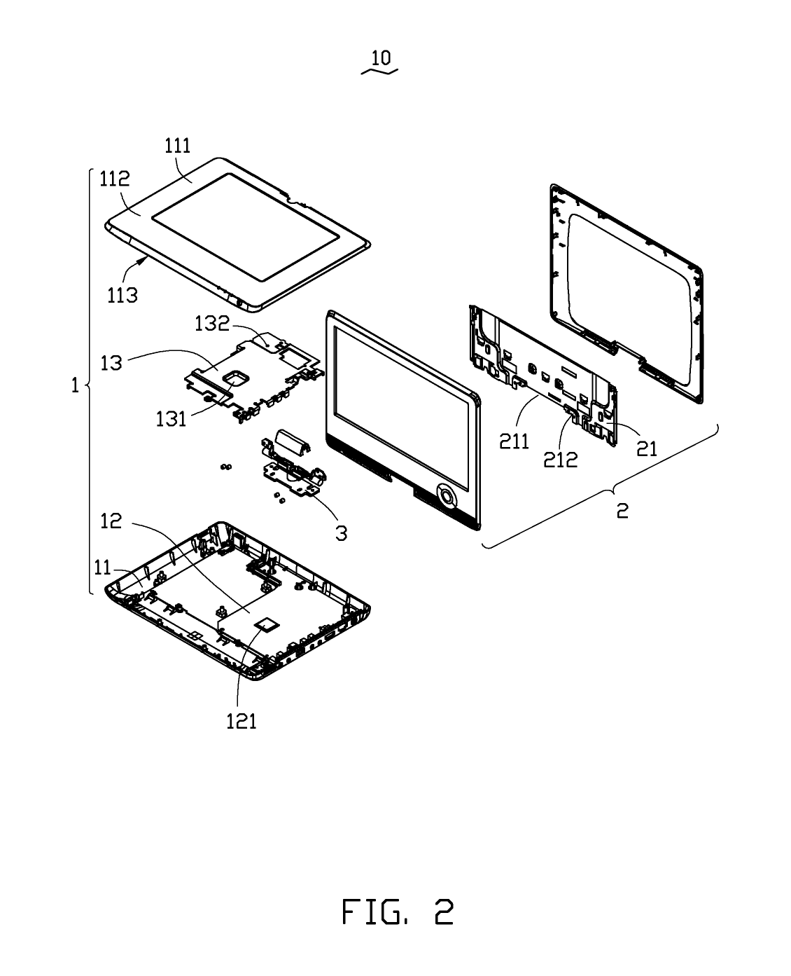

Referring to FIG. 1 and FIG. 2, a portable electronic device 10, in this embodiment, a notebook computer, includes a mainframe 1, a display panel 2 and a hinge 3. The display panel 2 is pivotably connected to the mainframe 1 by the hinge 3. As such, the display panel 2 is capable of rotating relative to the mainframe 1.

The mainframe 1 includes a case 11, a circuit board 12 and a heat sink 13. The circuit board 12 and the heat sink 13 are received in the case 11. The heat sink 13 is mounted on the circuit board 12 for dissipating heat of a heat-generating component 121 arranged on the circuit board 12.

The case 11 has a hollow and cuboid configuration for receiving the circuit board 12 and the sink 13. The case 11 includes an upper plate 111 with a top surface 112 and a bottom surface 113. The top surface 112 includes a recess (not labeled) defined in the central portion for receiving a keyboard (not illustrated).

The heat sink 13 is a planar plate located on the top side of the circuit board 12. The heat sink 13 includes two through holes 132 defined substantially on two different corners. The heat sink 13 further defines a recess 131 opposite to the heat generating component 121. When assembled together, the heat sink 13 covers the circuit board 12 and a bottom of the recess 131 abuts against a top surface of the heat generating component 121. Thereby, the heat sink 13 tightly contacts the heat generating component 121 to dissipate heat.

The display panel 2 includes an electromagnetic interference (EMI) shielding board 21 made of high heat conductivity materials such as copper, and aluminum. In this embodiment, the EMI shielding board 21 has a rectangular shape with an opening 211 substantially at the middle near the bottom. Two lateral sides of the opening 211 protrude towards the mainframe 1, each define at least one through hole 212.

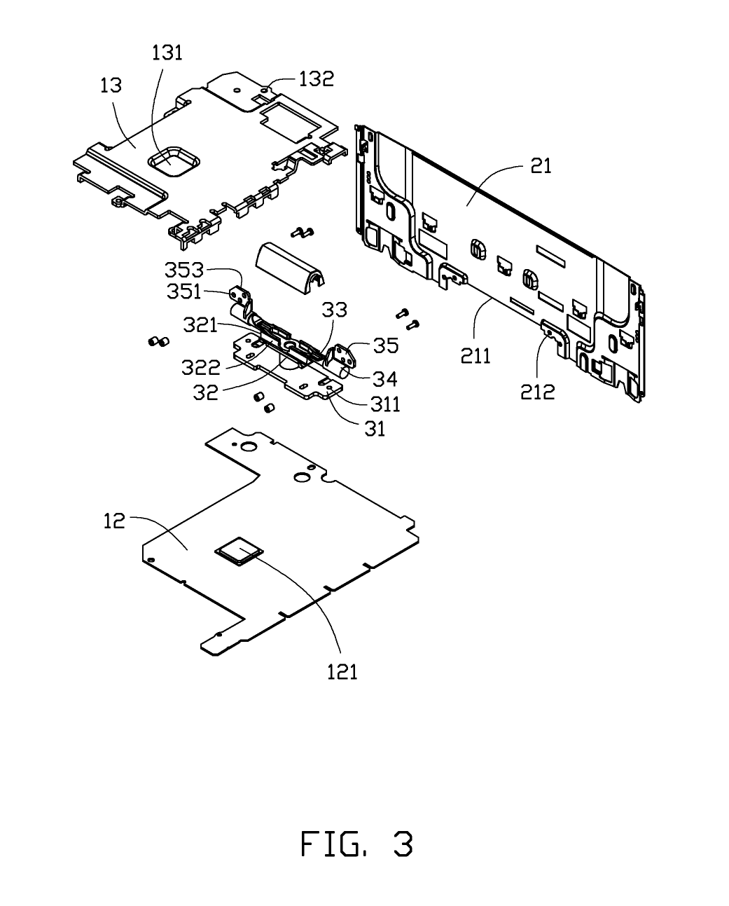

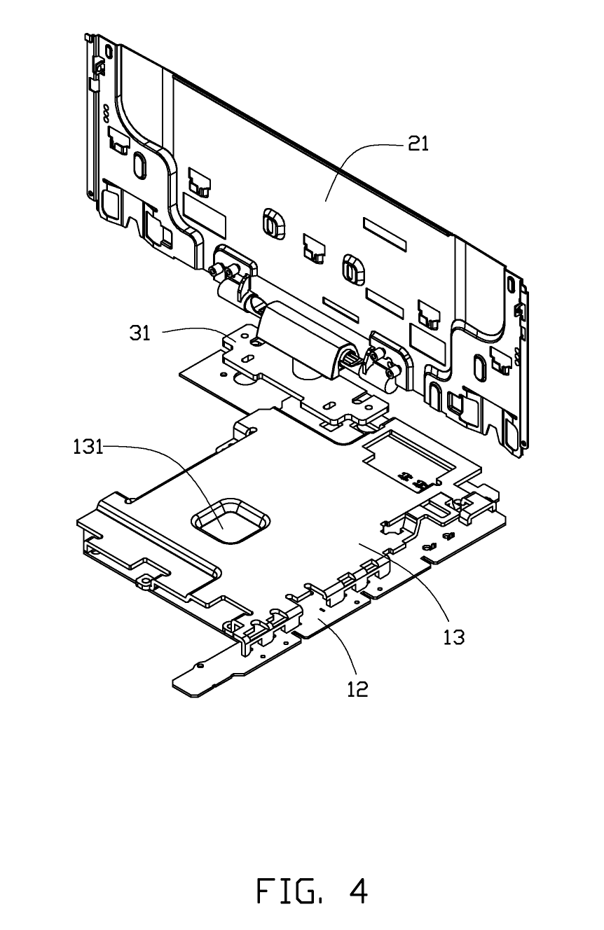

Referring to FIG. 3 and FIG. 4, the hinge 3 is made of high heat conductive materials. The hinge 3 includes a bottom plate 31, a holding section 32, a rotation shaft 33, a bushing 34, and a bracket 35. The bottom plate 31 is fixed on the heat sink 13. The holding section 32 is fixed on the bottom plate 31. The holding section 32 extends, from a middle of a lateral side of the bottom plate 31, along a direction perpendicular to and away from the bottom plate 31. The rotation shaft 33 is fixed to a lateral side of the holding section 32 away from the bottom plate 31. The bushing 34 encases the rotation shaft 33. The bracket 35 is connected to a peripheral sidewall of the bushing 34. As such, the bracket 35 is capable of rotating relatively to the bottom plate 31 around the rotation shaft 33. The bracket 35 is connected to the EMI shielding board 21. Accordingly, heat generated by the heat generating component 121 can be transferred to the EMI shielding board 21 via the heat sink 13 and the hinge 3.

In this embodiment, the hinge 3 includes two rotation shafts 33, two bushings 34 and two brackets 35.

The bottom plate 31 is fixed on the heat sink 13. The bottom plate 31 has two opposite through holes 311 defined at each side. The two through holes 311 on right side of the bottom plate 31 face and communicate with the through holes 132 defined on the heat sink 13. Accordingly, the bottom plate 31 can be fixed to the heat sink 13 with bolts (not illustrated) penetrating through the through holes 311, 132. Furthermore, the bottom plate 31 can be fixed to the upper plate 111 with bolts penetrating through the two through holes 311 on left side of the bottom plate 31 embedded in the upper plate 111.

The holding portion 32 extends from a middle of a lateral side of the bottom plate 31. The holding portion 32 is formed in a T-shape with a crossbar of the T projecting sideways in opposite directions.

The two rotation shafts 33 are fixed respectively on one end 321 of the crossbar of the T-shape holding portion 32. The two rotation shafts 33 are symmetric to each other. Each rotation shaft 33 includes a cylindrical portion.

The two bushings 34 respectively encasing one cylindrical portion of the two rotation shafts 33. The two bushings 34 each have a hollow cylindrical body with an internal diameter slightly larger than an external diameter of the cylindrical portion of the rotation shaft 33. As such, each of the bushings 34 rotates around the corresponding rotation shaft 33.

The two brackets 35 are respectively secured to one peripheral sidewall of the two bushings 34. The two brackets 35 each include a supporting plate 351 and a fixing plate 352 defined at a lateral side of the supporting plate 351. The supporting plate 352 is fixed on the peripheral sidewall of the bushings 34 and perpendicular to a longitudinal axis of the rotation shaft 33. The fixing plate 352 is perpendicular to the supporting plate 351 and adjacent to the EMI shielding board 21. The fixing plate 352 defines at least one through hole 353. As such, the fixing plate 352 can be fixed to the EMI shielding board 21 with bolts passing through the through holes 353 and the through holes 212.

Due to the fact that the hinge 3 and the EMI shielding board 21 are both made of high heat conductive materials. Heat from the heat generating component 121 can be successively transferred to the heat sink 13, the bottom plate 31, the holding portion 32, the rotation shaft 33, the bushing 34, the bracket 35 and the EMI shielding board 21. As an almost indispensable component in electronic device, the EMI shielding board 21 is capable of further acting as a heat dissipating plate. Thereby, heat dissipating efficiency can be greatly enhanced under help of the EMI shielding board 21, without adding any extra heat dissipating components for assistance.

It is to be understood that the above-described embodiments are intended to illustrate rather than limit the disclosure. Variations may be made to the embodiments without departing from the spirit of the disclosure as claimed. The above-described embodiments illustrate the scope of the disclosure but do not restrict the scope of the disclosure.

What is claimed is:

1. A portable electronic device comprising:
a circuit board equipped with a heat generating component;
a heat sink arranged on the heat generating component for dissipating heat generated by the heat generating component; and
a heat dissipating plate connected to the heat sink by a hinge, the heat dissipating plate aiding heat dissipation of the heat sink.

2. The portable electronic device of claim 1, wherein the heat sink is a planar plate covering the circuit board.

3. The portable electronic device of claim 2, wherein the heat sink has a recess with a bottom abutting against the heat generating component.

4. The portable electronic device of claim 1, wherein the hinge comprises a bottom plate and a bracket capable of rotating relative to each other, the bottom plate being secured to the heat sink, the bracket being secured to the heat dissipating plate.

5. The portable electronic device of claim 4, wherein the hinge further comprises a rotation shaft, a holding section holding the rotation shaft and a bushing encasing the rotation shaft, the rotation shaft being fixed to the holding section, the holding section being secured to the bottom plate, the bushing being capable of rotating around the rotation shaft, the bracket being secured to a peripheral sidewall of the bushing.

6. The portable electronic device according claim 5, wherein the rotation shaft comprises a cylindrical portion encased by the shaft.

7. The portable electronic device according claim 6, wherein the bracket comprises a supporting plate and a fixing plate configured at a lateral side of the supporting plate, the supporting plate being fixed on the peripheral sidewall of the bushings and perpendicular to a longitudinal axis of the rotation shaft, the fixing plate being perpendicular to the supporting plate and adjoined to the heat dissipating plate.

8. A portable electronic device comprising:
a casing;
a heat generating component disposed in the casing;
a heat sink received in the casing and attached to the heat generating component;
a panel pivotably connected to the casing by a hinge, the panel comprising a display screen and a board, the hinge interconnecting the heat sink and the board for transferring heat from the heat sink to the board for dissipation.

9. The portable electronic device of claim 8, wherein the heat sink is a planar plate.

10. The portable electronic device according claim 9, wherein the heat sink has a recess with a bottom abutting against the heat generating component.

11. The portable electronic device according claim 8, wherein the hinge comprises a bottom plate and a bracket capable of rotating relative to each other, the bottom plate being secured to the heat sink, the bracket being secured to the board.

12. The portable electronic device according claim 11, wherein the hinge further comprises a rotation shaft, a holding section holding the rotation shaft and a bushing encasing the rotation shaft, the rotation shaft being fixed to the holding section, the holding section being secured to the bottom plate, the bushing being capable of rotating around the rotation shaft, the bracket being secured to a peripheral sidewall of the bushing.

13. The portable electronic device according claim 12, wherein the rotation shaft comprises a cylindrical portion encased by the shaft.

14. The portable electronic device according claim 13, wherein the bracket comprises a supporting plate and a fixing plate configured at a lateral side of the supporting plate, the supporting plate being fixed on the peripheral sidewall of the bushings and perpendicular to a longitudinal axis of the rotation shaft, the fixing plate being perpendicular to the supporting plate and adjoined to the board.
